(19) United States
(12) Patent Application Publication
(10) Pub. No.: US 2017/0232562 A1
(43) Pub. Date: Aug. 17, 2017

(54) BONDING STRUCTURE, BONDING MATERIAL AND BONDING METHOD

(71) Applicant: KABUSHIKI KAISHA TOYOTA JIDOSHOKKI, Kariya-shi, Aichi-ken (JP)

(72) Inventor: Kazuhiro MAENO, Kariya-shi (JP)

(73) Assignee: KABUSHIKI KAISHA TOYOTA JIDOSHOKKI, Kariya-shi, Aichi-ken (JP)

(21) Appl. No.: 15/503,093

(22) PCT Filed: Jul. 14, 2015
(86) PCT No.: PCT/JP2015/070119

§ 371 Date: Feb. 10, 2017

(30) Foreign Application Priority Data
Aug. 22, 2014 (JP) 2014-169548

(51) Int. Cl. B23K 35/26; H01L 23/00; B23K 35/30; B23K 1/20; B23K 35/02

(52) U.S. Cl. CPC B23K 35/262; B23K 1/20; B23K 35/0238; B23K 35/302; H01L 24/32; H01L 24/83; B23K 2201/40

(57) ABSTRACT

A bonding structure bonds a Cu wiring line and a device electrode with each other. The bonding structure is arranged between the Cu wiring line and the device electrode, and comprises a first intermetallic compound (IMC) layer (a layer of an intermetallic compound of Cu and Sn) formed on the interface with the Cu wiring line, a second intermetallic compound (IMC) layer (a layer of an intermetallic compound of Cu and Sn) formed on the interface with the device electrode, and an intermediate layer that is present between the intermetallic compound layers. In the intermediate layer, a network-like IMC (a network-like intermetallic compound of Cu and Sn) is present in Sn.

### TECHNICAL FIELD

The present invention relates to a lead-free bonding structure that withstands the temperature on the high temperature side of temperature hierarchical connection, a bonding material for forming the bonding structure, and to a bonding method.

### BACKGROUND ART

In accordance with to the recent environmental measures, lead has been eliminated from solders used as bonding materials, for example, for mounting electronic components. In particular, almost 100% of lead has been eliminated in low temperature soldering that is most commonly used, at present. On the other hand, in high temperature soldering used for hierarchical soldering, the technical hurdle is high, and a practical lead-free solder has not been developed. Therefore, the use of lead in high temperature soldering is exempted from the regulations.

For the high temperature soldering, a Pb-5Sn solder is used in most cases. This solder is often used because it has a melting point of 303/305° C., which is suitable for hierarchical soldering, and further has good wettability and good thermal shock resistance.

In contrast, in order to replace the high temperature lead soldering and eliminate lead, a solder foil as a lead-free bonding material used for connection on the high temperature side in a temperature hierarchical connection and obtained by rolling a solder material containing Cu particles and Sn particles as solder particles has been proposed (see Patent Document 1). In this solder foil, when the solder foil disposed between members is heated, molten Sn and Cu particles react with each other, and the Cu particles are bonded together by Cu₆Sn₅ (intermetallic compound). As a result, the joint strength by the solder foil is ensured even at 280° C.

However, the bonding material of Patent Document 1 is formed by rolling the solder material containing Cu particles and Sn particles, and thus the Cu particles and the Sn particles need to be uniformly mixed. Therefore, not only is the mixing operation time consuming, but the production cost to achieve a certain thickness by rolling is high. Further, Cu₆Sn₅, which is an intermetallic compound of Cu and Sn, itself has poor wettability and further has hard and brittle properties. Further, in the case of compression molding after mixing the particles as in Patent Document 1, the entire region of the bonding structure is uniformly composed of a large amount of Cu₆Sn₅, and therefore there is a possibility of deterioration in wettability and poor thermal shock resistance.

Further, in Patent Document 1, compression molding is performed after mixing the Cu and Sn particles and therefore it is difficult to sufficiently reduce voids. That is, gaps among Cu balls are filled by plastic flow of Sn in compression molding in Patent Document 1, and thus the gaps of the Cu balls are not filled by melting Sn. In this case, it is difficult to completely fill the fine gaps among the Cu balls only by the plastic flow of Sn. Therefore, in conventional Cu and Sn particle-containing paste soldering, voids are reduced to some extent, but voids cannot be reduced to the level of lead soldering.

Patent Document 1 also discloses that heat is generated to some extent in compression molding, and the temperature is slightly increased in order to increase the fluidity of the Sn. In this case, formation of the intermetallic compound Cu₆Sn₅ between the Cu and Sn particles cannot be avoided. This is because Cu is susceptible to diffusion reaction with Sn, and thus Cu easily reacts with Sn even under a temperature increase to an extent in which Sn does not melt. In this case, the fluidity of Sn is reduced in compression molding due to the presence of the intermetallic compound Cu₆Sn₅, and voids further tend to form.

Further, when the intermetallic compound Cu₆Sn₅ is formed before bonding, the bonding properties by the solder foil are reduced. This is because the intermetallic compound Cu₆Sn₅ itself has poor wettability, as described above, and therefore inhibits wetting of the particle-containing Sn.

### PRIOR ART DOCUMENT

### Patent Document

### Patent Document 1: Japanese Laid-Open Patent Publication No. 2004-247742

### SUMMARY OF THE INVENTION

### Problems that the Invention is to Solve

It is an objective of the present invention to provide a lead-free bonding structure in which fluxless bonding operation is possible and which has properties equivalent to those of the bonding structure bonded by conventional high temperature lead soldering, a bonding material for forming the bonding structure, and a bonding method.

To achieve the foregoing objective and in accordance with a first aspect of the present invention, a bonding structure is provided that is configured to bond a first member and a second member together. Sn layered on Cu is disposed between the first member and the second member before bonding. Cu and Sn form an intermetallic compound to bond the first member and the second member together.

In the configuration of the present invention, since Cu and Sn are layered, molten Sn reliably fills the interface of Cu without gaps in bonding to form an intermetallic compound in layer form over the entire surface of the Cu. Therefore, voids forming in the unfilled portion in gaps surrounding Cu balls as in Patent Document 1 can be eliminated, and thus good bonding is achieved.

Further, the plastic flow of Sn by compression molding as in Patent Document 1 is not needed. Therefore, the generation of the intermetallic compound before bonding is suppressed, and the molten Sn easily contacts the entire surface of the Cu in bonding. Therefore, good wettability is ensured.

Further, since Cu and Sn are layered, fluxless bonding is possible unlike the paste solder having a ball structure.

In the above described bonding structure, the intermetallic compound is preferably disposed as a layer on the entire surface of each of the interface of the first member and the interface of the second member at the bonding part. The intermetallic compound is preferably dispersed in the form of a network within a Sn rich layer present between the interface of the first member and the interface of the second member so as to connect the two interfaces.

The network structure of the intermetallic compound (IMC) is considered to be effective for thermal shock resistance. That is, the IMC having a comparatively hard property has a network structure of the IMC particles that are widely dispersed in a diluted state and precipitated in the three-dimensional direction. Therefore, the IMC is easily deformed due to its structure. Moreover, the single Sn filling the periphery of the IMC has good malleability and good ductility. Therefore, it can absorb the thermal stress generated at the bonding part.

In the above described bonding structure, the Cu is preferably disposed, before the bonding, by at least any one of the first member, the second member, and a layer of another member. This configuration reduces the labor to dispose Cu.

In the above described bonding structure, the Sn and the Cu are preferably layered in direct contact with each other. In this configuration, the bonding structure is simple as compared with the case where another layer is present between Sn and Cu.

In the above described bonding structure, the Sn and the Cu are preferably layered with a Ni layer disposed between the Sn and the Cu. In this configuration, the Ni layer delays the contact between the Sn and the Cu during the time when the Sn, which has good wettability, melts and its wetting sufficiently spreads. This prevents wetting inhibition immediately after the melting of the Sn due to the IMC formation, and ensures the time in which the wetting by the Sn spreads. Thereafter, the IMC that functions as a high temperature bonding material is formed, and therefore both good wetting by the Sn and high temperature bonding by the IMC are achieved.

The above described bonding structure preferably includes, between the first member and the second member, an intermetallic compound layer of Cu and Sn formed on the interface of the first member, an intermetallic compound layer of Cu and Sn formed on the interface of the second member, and an interlayer that is present between the two intermetallic compound layers and in which a network-like intermetallic compound of Cu and Sn is present in Sn.

Cu₆Sn₅, which is the intermetallic compound of Cu and Sn, does not melt until its melting point of 415° C. is reached. However, Cu₆Sn₅ itself has poor wettability and further has hard and brittle properties. Therefore, in the case where the most part of the bonding structure is uniformly composed of Cu₆Sn₅, there is a possibility of deterioration in wettability and poor thermal shock resistance, which is undesirable. On the other hand, Sn has good wettability and further tends to have good malleability and good ductility as compared with Cu₆Sn₅.

In the configuration of the present invention, the bonding structure configured to bond the first member and the second member together includes an intermetallic compound of Cu and Sn formed on the interface of the first member, an intermetallic compound of Cu and Sn bonded to the interface of the second member, and an interlayer that is present between the two intermetallic compound layers and in which a network-like intermetallic compound of Cu and Sn is present in the Sn. Therefore, unlike the case where the entire bonding structure is uniformly composed of the intermetallic compound of Cu and Sn, the interlayer in which the network-like intermetallic compound of Cu and Sn is present in the Sn exerts wettability and thermal shock resistance. This ensures good wettability equivalent to that of Sn and high thermal shock resistance. Further, the bonding operation can be performed at a temperature of about 250 to 350° C., which is higher than the melting point of Sn and is equal to or lower than the temperature in conventional lead soldering and at which the intermetallic compound of Cu and Sn melts into Sn. Also, after once bonded, the bonding is ensured until a high melting point of 415° C. Accordingly, fluxless bonding operation is possible, properties equivalent to those of the bonding structure bonded by conventional lead soldering can be given, while eliminating lead.

In the case where the use environment is in a high temperature region equal to or higher than the melting point of Sn, Sn remelts alone in the Sn rich layer in which the Cu₆Sn₅ IMC is formed in the form of a network. It is estimated that this has a great influence on the thermal shock resistance. This is because only the IMC network in which the structure connecting the bonding part is easily deformed is left by the remelting of Sn, and most part of the thermal stress generated at the bonding part is released. This characteristic is particularly useful in a high temperature operating environment of around 300° C. that is predicted in future in compound semiconductors.

In the above described bonding structure, the interface of one of the two intermetallic compound layers preferably has larger asperities than the interface of the other intermetallic compound layer. Therefore, the anchor effect makes it difficult for the member bonded via one of the two intermetallic compound layers to separate from the interlayer.

In the above described bonding structure, the first member preferably comprises Cu, and the intermetallic compound layer of Cu and Sn formed on the interface of the first member preferably comprises a Cu₃Sn layer and a Cu₆Sn₅ layer. In this configuration, as compared with the case where only Cu₆Sn₅ is present between the Cu as the first member and the interlayer, the difference in coefficient of thermal expansion between adjacent layers that are present from the interlayer to the Cu is reduced, and the thermal shock resistance is improved.

To achieve the foregoing objective and in accordance with a second aspect of the present invention, a bonding material is provided that includes a Cu layer and a Sn layer present at least on the entire one surface of the Cu layer.

According to the bonding material having this configuration, for example, in the case where a device is bonded onto a Cu wiring, a Sn layer is layered on the Cu wiring to contact at least the entire one surface of the Cu layer, and the device is placed further thereon. Then, it is heated to about 250 to 350° C., which is higher than the melting point of Sn and at which molten Sn forms an intermetallic compound with Cu. Upon melting by the heating, the Sn immediately reacts with the Cu. Then, an intermetallic compound of Cu and Sn (IMC) is formed on the interface of the Cu wiring. At that time, the remaining Sn that did not form the IMC is in a molten state. When the IMC is partially dissolved in the Sn, the dissolved IMC moves within the Sn and mostly gathers on the interface of the device electrodes. This forms an IMC layer on the interface of the device electrodes. Accordingly, the Cu layer and the Sn layer are arranged to be layered, and therefore fluxless bonding operation is possible. Further, since the IMC is partially dissolved in the IMC layer and the Sn, properties equivalent to those of the bonding structure bonded by conventional lead soldering can be given.

In the above described bonding material, the Cu layer and the Sn layer preferably constitute a clad material. In the case where the bonding material is a clad material with a Cu layer and a Sn layer, the workability in use is improved, as compared with the case where separate foils are layered.

In the above described bonding material, the Sn layer preferably comprises a plating layer formed on the Cu layer. In the case of forming the Sn layer by metal plating, a thin layer can be easily layered. Further, in the case of using a Sn foil placed on a Cu foil as a bonding material, the Sn foil is placed on the oxidized surface of the Cu foil. In this case, in order to avoid the adverse effects of the oxide film, the operation needs to be performed in a H₂ reduction furnace. However, in the case where the Sn layer is formed by metal plating, the oxidation coating is not formed between the Cu layer and the Sn layer.

In the above described bonding material, the Cu layer and the Sn layer preferably comprise foils. In this case, a foil processed into a predetermined thickness in advance is used, and therefore the thickness can be easily controlled.

In the above described bonding material, the Cu layer preferably comprises a Cu plate, and the Sn layer preferably comprises of a foil. In this case, the Sn foil is placed on an oxidized surface of a Cu plate, and therefore adverse effects of the oxide film are expected. In order to avoid the adverse effects, the bonding operation is preferably performed in a H₂ reduction furnace. In the case of a Cu plate with anti-oxidation coating formed on its surface, the operation can be performed also in an air atmosphere furnace instead of the reduction furnace. However, the anti-oxidation film is required to have a thickness that allows Sn to diffuse in Cu upon melting and does not inhibit the IMC formation.

Further, the thickness can be easily controlled by using a Cu plate and foils processed into a predetermined thickness in advance.

To achieve the foregoing objective and in accordance with a third aspect of the present invention, a method for bonding a first member and a second member together is provided. The method includes: heating Sn layered on Cu between the first member and the second member; and forming an intermetallic compound of Cu and Sn between the first member and the second member to bond the first member and the second member together.

### Effects of the Invention

According to the present invention, fluxless bonding operation can be performed, and the bonding structure is lead-free and has properties equivalent to the bonding structure bonded by conventional high temperature lead soldering.

### BRIEF DESCRIPTION OF THE DRAWINGS

FIG. 1 is a schematic diagram showing a bonding structure of a first embodiment.

FIG. 2 is a schematic diagram showing a relationship between a semiconductor device and a wiring board before bonding.

FIG. 3 is a schematic diagram of an elemental map of the bonding structure.

FIG. 4 is a schematic diagram showing a bonding method of a second embodiment.

FIG. 5A is a schematic diagram showing a relationship between a semiconductor device and a wiring board before bonding of a third embodiment.

FIG. 5B is a schematic diagram of a bonding structure.

FIG. 6 is a schematic diagram showing a bonding method of a fourth embodiment.

FIG. 7 is a schematic diagram showing a relationship between a semiconductor device and a wiring board before bonding of another embodiment.

### MODES FOR CARRYING OUT THE INVENTION

### First Embodiment

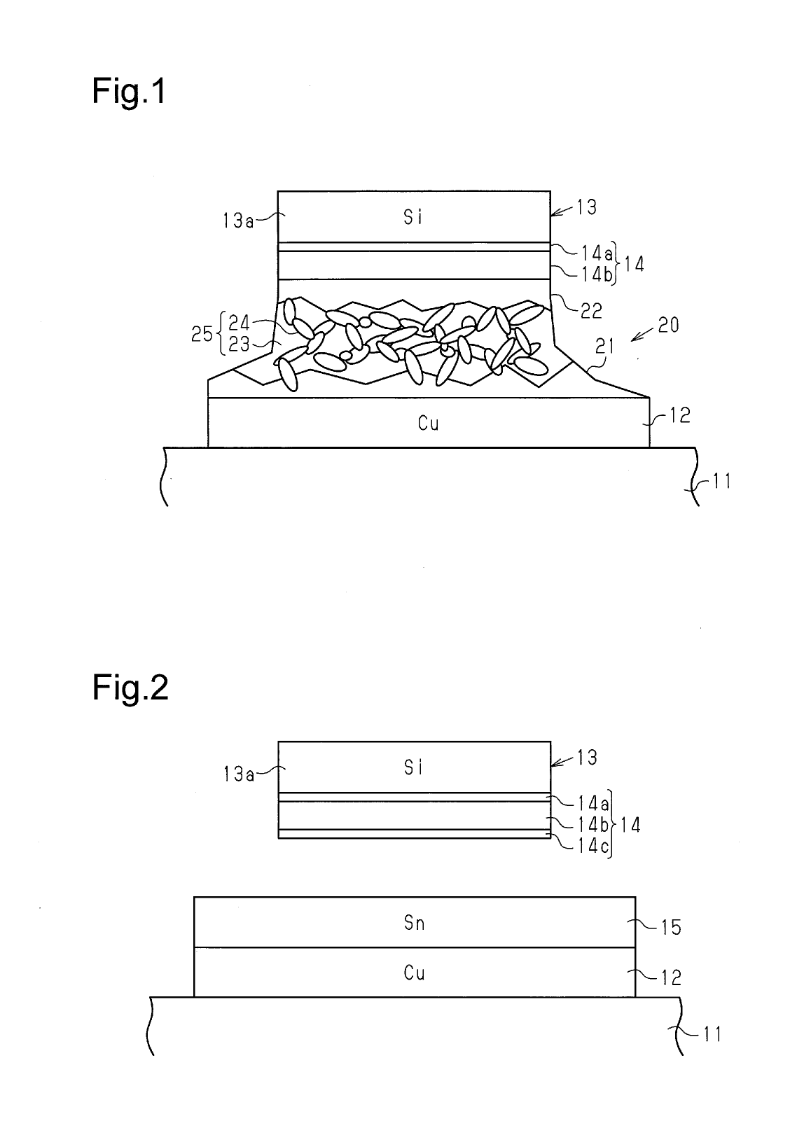

Hereinafter, a first embodiment in which the present invention is applied to the mounting of a semiconductor device onto a wiring of a wiring board will be described with reference to FIGS. 1 to 3.

As shown in FIG. 1, a device electrode 14 of a semiconductor device (such as MOS chip) 13 as a second member is bonded onto a Cu wiring line 12 formed on a wiring board 11 as a first member via a bonding structure 20. The device electrode 14 formed on the back of the semiconductor device 13 is formed by layering a Ti layer 14a and a Ni layer 14b sequentially from the side of a Si device body 13a.

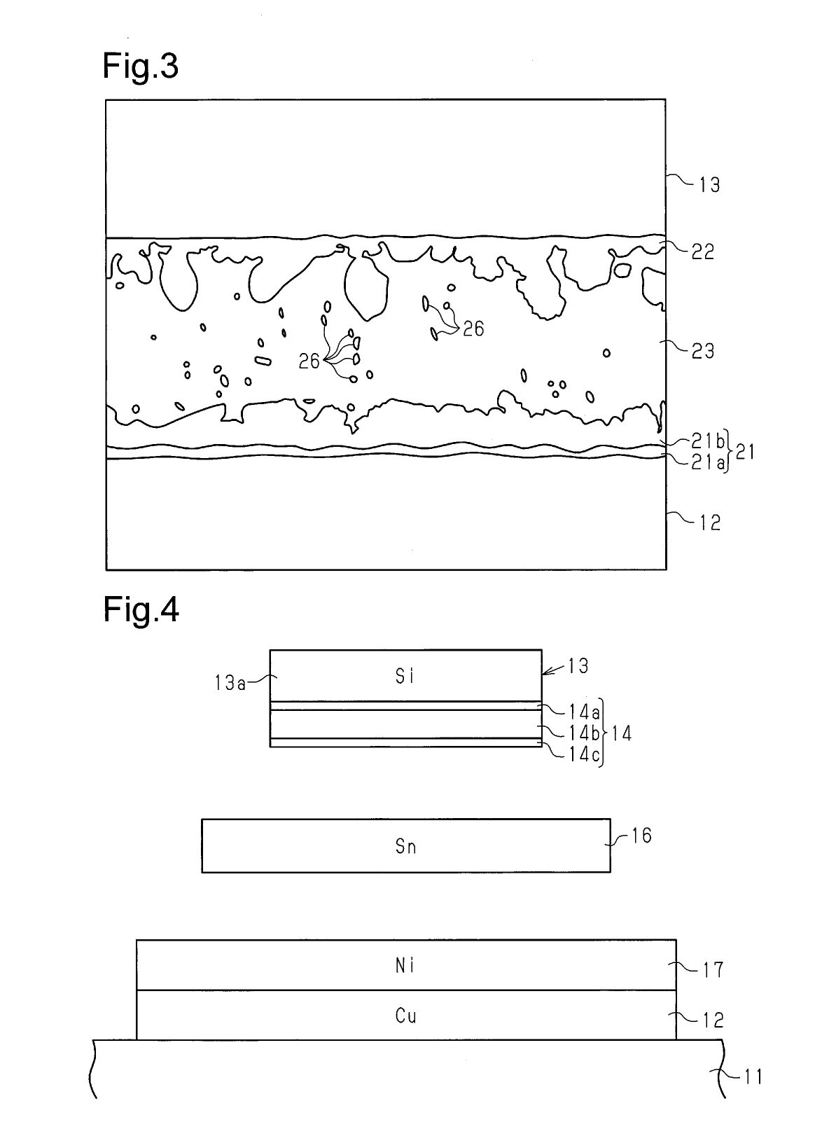

The bonding structure 20 is configured to bond the first member and the second member together and is present between the Cu wiring line 12 and the semiconductor device 13. The bonding structure 20 includes a first IMC layer 21, a second IMC layer 22, and an interlayer 25. The first IMC layer 21 is an intermetallic compound layer of Cu and Sn (IMC layer) formed on the interface of the Cu wiring line 12. The second IMC layer 22 is an intermetallic compound layer of Cu and Sn formed on the interface of the semiconductor device 13. The interlayer 25 is present between the first IMC layer 21 and the second IMC layer 22. In the interlayer 25, a network-like IMC 24 as an intermetallic compound of Cu and Sn is present in Sn 23. As shown in FIG. 3, the first IMC layer 21 is composed of a Cu₃Sn layer 21a and a Cu₆Sn₅ layer 21b.

Next, a method for bonding the semiconductor device 13 onto the Cu wiring line 12 of the wiring board 11 will be described.

As shown in FIG. 2, the semiconductor device 13 was placed on the Cu wiring line 12 having a Sn plating 15 on its entire surface. In this stage, the device electrode 14 of the semiconductor device 13 was formed by layering a Ti layer 14a, a Ni layer 14b, and an Au layer 14c sequentially from the Si device body 13a side. The thickness of the Sn plating 15 was 1 to 3 μm, the thickness of the Ti layer 14a was 0.15 μm, the thickness of the Ni layer 14b was 0.53 μm, and the thickness of the Au layer 14c is 0.1 μm.

Thereafter, only the Sn plating 15 was melted in a H₂ reduction furnace at a temperature of about 440° C. to form the bonding structure 20 having an intermetallic compound layer of Cu and Sn between the Cu wiring line 12 and the device electrode 14, so that the Cu wiring line 12 and the semiconductor device 13 were bonded together. In this case, the intermetallic compound layer of Cu and Sn was sufficiently formed even at about 240° C., which is a bonding temperature level of low temperature soldering, but the temperature was raised to about 440° C. in order to reliably ensure the wettability by H₂ reduction.

As a result of bonding, good bonding with an average void fraction of 3% was obtained. The void fraction was calculated from the area ratio of the void portion using an X-ray image obtained by capturing the bonding structure 20.

Further, in order to check whether high temperature bonding had been performed as intended without remelting at about 300° C., a workpiece was arranged perpendicularly to a device, and then the workpiece was reintroduced into a H₂ reduction furnace with a peak temperature of 327° C. As a result, dropping and displacement of the device did not occur at all. It was confirmed from this that high temperature bonding as intended had been achieved.

In order to investigate the presence or absence of a single Sn layer, the thickness of the first IMC layer 21 and the second IMC layer 22, and the like, in detail, scanning electron microscope (SEM) observation of the cross section and elemental mapping analysis were performed. As a result, the presence of the first IMC layer 21 on the interface of the Cu wiring line 12 of the wiring board 11, the presence of the second IMC layer 22 on the interface of the device electrode 14 of the semiconductor device 13, and the presence of a layer that seemed to be a single Sn layer therebetween were observed.

It turned out that the thickness of the first IMC layer 21 was about 9 μm, the thickness of the second IMC layer 22 was about 5 μm, the thickness of the layer which seems to be a single Sn layer was about 29 μm, and the thickness of the bonding structure (bonding layer) 20, which was the total of the aforementioned layers, was about 43 μm.

As shown in FIG. 1, the device electrode 14 after the bonding structure 20 was formed was formed by layering the Ti layer 14a and the Ni layer 14b sequentially from the Si device body 13a side, and the Au layer 14c that was present before bonding disappeared. This is probably because Au having high Au diffusivity diffused into molten Sn.

In these analysis results, there were two obscure points.

One point is that while the original thickness of the Sn plating 15 was about 1 to 3 μm, the thickness of the resultant bonding structure 20 was about 20 times the original thickness. Another point is that it was confirmed that remelting did not occur at 327° C., as described above, and if the single Sn layer (mp: 232/234° C.) is present, the presence thereof contradicts the aforementioned results.

The former obscure point is estimated due to the increase in thickness resulted from the fact that Sn in the region of the Sn plating 15 on the entire surface of the Cu wiring line 12 other than the region subjected to die bonding gathered around the die bonding region after the melting. In order to support this estimation, the Sn plating 15 in the region other than the region subjected to die bonding was removed, and the same die bonding was performed. As a result, the bonding structure (bonding layer) 20 did not spread to the entire region of die bonding, and the Cu wiring line 12 and the semiconductor device 13 were bonded only at partial points. This means that the amount of Sn was insufficient, and the IMC was not sufficiently formed. The aforementioned estimation was supported by these results.

For the latter obscure point, the layer that appeared to be a single Sn layer was subjected to detailed elemental mapping analysis. As a result, as shown in FIG. 3, fine Cu element masses 26 having the same concentration level as the IMC (Cu₆Sn₅) were scattered in some places within the aforementioned layer. It is considered from this that the IMC was scattered in the layer that seemed a single Sn layer and were connected to each other in the form of a network. That is, it turned out that the interlayer 25 having the network-like IMC 24 as an intermetallic compound of Cu and Sn was present between the first IMC layer 21 and the second IMC layer 22 in the Sn 23.

As a result of this, it is estimated that, even in a high temperature state that is equal to or higher than the melting point of Sn, the network-like IMC 24 that is present in the layer connects the first IMC layer 21 and the second IMC layer 22 together, thereby allowing the entire bonding structure 20 to function as a high temperature bonding material without remelting, although the single Sn remelts.

Further, the first IMC layer 21 was not a single layer, in which two layers of the Cu₃Sn layer 21a and the Cu₆Sn₅ layer 21b were layered together with the Cu₃Sn layer 21a arranged in the vicinity of the Cu wiring line 12. This is probably because die bonding was performed by forming the bonding structure 20 having an intermetallic compound layer of Cu and Sn between the Cu wiring line 12 and the device electrode 14 by melting only the Sn plating 15 at a temperature of about 440° C. in the H₂ reduction furnace, and therefore the Cu₃Sn layer 21a was formed in the vicinity of the Cu wiring line 12, which was Cu rich. Since the melting point of Cu₃Sn is higher than the melting point of Cu₆Sn₅ of 415° C., the presence of Cu₃Sn does not cause a reduction in melting point that impairs the function as a high temperature bonding material.

It turned out from the aforementioned results that, in the bonding material for obtaining the bonding structure 20 that withstands a high temperature of 300° C. or higher, the Sn thickness of about 43 μm before bonding is sufficient to obtain good bonding, whereas the thickness of 1 to 3 μm is insufficient. Further, it is estimated that, immediately upon melting due to the temperature increase, Sn reacts with Cu to form the IMC layer, and the residual components form a Sn rich layer, that is, the interlayer 25. It is expected from this that, in the case where the Sn thickness before bonding is 14 μm or less, which is the total thickness of the first IMC layer 21 and the second IMC layer 22, the Sn rich layer is formed in a small part, and the IMC layer is formed in most part.

The IMC has poor wettability and hard and brittle properties. Meanwhile, Sn has good wettability and has good malleability and good ductility, as compared with the IMC. Therefore, when most part of the bonding structure 20 is formed by the IMC, there is a possibility of deterioration in wettability and poor thermal shock resistance, which is not preferable. Meanwhile, it is preferable to allow the Sn rich layer to remain between the first IMC layer 21 and the second IMC layer 22, in view of wettability and thermal shock resistance.

Therefore, the Sn thickness before bonding is preferably 14 μm or more. However, when the thickness of the Sn layer is excessively large, the network-like IMC 24 is not sufficiently formed after the melting, and the single Sn layer remains. As a result, the single Sn layer completely remelts when the temperature increases, and there is a possibility of dropping and displacement of the device.

It is difficult to accurately specify the upper limit of the Sn thickness from the present evaluation results. For example, it is assumed that, in consideration of the distribution state of a trace amount of the IMC formed within the Sn rich layer in the aforementioned cross sectional elemental map, a distribution concentration at which the IMC can form a network can be maintained up to the thickness, with which the network-like IMC 24 can be formed in the Sn rich layer, of about twice the thickness of the IMC layer. From this assumption, a thickness of about 72 μm obtained by adding 29 μm to the present thickness of 43 μm is estimated as the upper limit of the Sn thickness. Therefore, the Sn thickness before bonding is preferably about 14 to 72 μm, more preferably around 40 μm, in particular.

It has been discovered that the first IMC layer 21 is present in the vicinity of the Cu wiring line 12, and the second IMC layer 22 is present in the vicinity of the device electrode 14 as the IMC layers. In the vicinity of the Cu wiring line 12, Cu is present, and therefore there is no contradiction in the fact that the IMC is present. However, there is a contradiction in the fact that the IMC is present in the vicinity of the device electrode 14, where Cu is not present originally. As a result of technical research and consideration, the inventor has found that the IMC originally occurs only in the vicinity of the Cu wiring line 12, and thereafter the IMC partially moves to the device electrode 14.

That is, the IMC is formed on the interface of the Cu wiring line 12 immediately after Sn melts by a temperature increase. At this time, the residual Sn that has not turned into the IMC is in a molten state. Further, as a result of the IMC being partially dissolved in Sn, the IMC is rendered in a supersaturated state. The dissolved IMC moves within Sn, and most of the IMC gathers on the interface of the device electrode 14. Thus, the second IMC layer 22 is formed on the interface of the device electrode 14. Actually, according to a cross sectional observation, the second IMC layer 22 that is present on the interface of the device electrode 14 has a shape with a larger particle size and larger asperities than the first IMC layer 21 on the interface of the Cu wiring line 12. This suggests that it is a result of the IMC formed on the interface of the Cu wiring line 12 partially moving to the interface of the device electrode 14 and gathering there.

Further, most of the dissolved IMC moves to the interface of the device electrode 14, but a small part of the dissolved IMC remains in the Sn layer as it is. It is estimated that the IMC thus remaining in the Sn layer leads to the network-like IMC 24 formed within the Sn rich layer.

Next, operation of the aforementioned bonding structure 20 will be described.

As described above, the IMC has poor wettability and hard and brittle properties. Meanwhile, Sn has good wettability and tends to have good malleability and good ductility as compared with the IMC. The bonding structure 20 of this embodiment includes the first IMC layer 21 bonded to the Cu wiring line 12, the second IMC layer 22 bonded to the device electrode 14, and the interlayer 25 between the first IMC layer 21 and the second IMC layer 22. In the interlayer 25, the network-like IMC 24 is present in the Sn 23. Therefore, good wettability equivalent to that of Sn can be ensured, and high thermal shock resistance is given. Further, the bonding operation can be performed at a temperature of about 250 to 350° C., which is higher than the melting point of Sn, at which molten Sn forms an intermetallic compound with Cu, and which is equal to or lower than the temperature of conventional lead soldering. Further, after once bonded, the bonding is ensured up to a high temperature melting point of 415° C. Accordingly, the arrangement is such that the Cu layer and the Sn layer are layered together, and thus fluxless bonding operation is possible. Further, the first IMC layer 21, the second IMC layer 22, and the interlayer 25 can give properties equivalent to those of the bonding structure bonded by conventional high temperature lead soldering.

Increasing the amount of Sn in the Sn rich layer is advantageous in view of the wettability and the thermal shock resistance. However, when the thickness of the Sn rich layer increases, the IMC network is insufficient, and there is a possibility of remelting at a high temperature exceeding the melting point of Sn (232° C.). Therefore, in order to achieve both of the aforementioned properties, it is important to control the Sn thickness before bonding to an appropriate value. As described above, the Sn thickness before bonding is preferably about 14 to 72 μm, more preferably around 40 μm, in particular.

The present embodiment achieves the following advantages.

(1) The bonding structure 20 is configured to bond the Cu wiring line 12 (the first member) and the device electrode 14 of the semiconductor device 13 (the second member) together. The bonding structure 20 includes the first IMC layer 21 (intermetallic compound layer of Cu and Sn) that is present between the Cu wiring line 12 and the device electrode 14 and is formed on the interface of the Cu wiring line 12, the second IMC layer 22 (intermetallic compound layer of Cu and Sn) formed on the interface of the device electrode 14, and the interlayer 25, which is present between the two intermetallic compound layers and in which the network-like IMC (network-like intermetallic compound of Cu and Sn) 24, is present in the Sn 23.

Therefore, the bonding structure 20 ensures good wettability equivalent to that of Sn and has high thermal shock resistance. Further, the bonding operation can be performed at a temperature of about 250 to 350° C., which is higher than the melting point of Sn, at which molten Sn forms an intermetallic compound with Cu, and which is equal to or lower than the temperature of conventional high temperature lead soldering. Further, after once bonded, the bonding is ensured up to a high temperature melting point of 415° C. Accordingly, fluxless bonding operation is possible, and properties equivalent to those of the bonding structure bonded by conventional high temperature lead soldering while eliminating lead are given.

(2) The interface between the second IMC layer 22 bonded to the device electrode 14 and the interlayer 25 has larger asperities than the interface between the first IMC layer 21 bonded to the Cu wiring line 12 and the interlayer 25. Therefore, the anchor effect makes it difficult for the device electrode 14 to separate from the interlayer 25.

(3) The first member comprises Cu, the second member comprises a metal other than Cu, and the intermetallic compound layer of Cu and Sn (the first IMC layer 21) bonded to the first member comprises the Cu₃Sn layer 21a and the Cu₆Sn₅ layer 21b. In this configuration, as compared with the case where only the Cu₆Sn₅ layer 21b is present between the Cu wiring line 12 as the first member and the interlayer 25, the difference in coefficient of thermal expansion between adjacent layers that are present from the interlayer 25 to the Cu wiring line 12 is reduced, and the thermal shock resistance is improved.

(4) The bonding structure 20 is formed by fusion bonding in a H₂ reduction furnace while the semiconductor device 13 is placed on a predetermined position of the Cu wiring line 12 having a surface subjected to the Sn plating 15. Accordingly, fluxless mounting is possible, and thus adverse effects due to flux residue are eliminated.

(5) In the production of the bonding structure 20, Cu as a board wiring and Sn as a plating layer of the board wiring are supplied while they are layered. Therefore, in bonding, molten Sn reliably fills the interface of Cu without gaps to form the intermetallic compound in layer form over the entire surface of Cu. Accordingly, voids forming in the unfilled portion between gaps in the periphery of balls as in Patent Document 1 are eliminated, and good bonding is obtained.

(6) In the production of the bonding structure 20, the IMC is formed by melting Sn, and therefore the plastic flow of Sn as in Patent Document 1 is not necessary. Therefore, the formation of the IMC is suppressed before bonding, and the molten Sn easily contacts the entire surface of Cu during bonding. Thus, good wettability is ensured.

### Second Embodiment

Next, a second embodiment will be described. The second embodiment is significantly different from the first embodiment in that Sn that is necessary for constituting the bonding structure 20 is bonded by using a Sn foil, instead of supplying it as the Sn plating 15 formed on the entire surface of the Cu wiring line 12. This Sn foil is processed into a size corresponding to the size of the device electrode 14 of the semiconductor device 13 that is subjected to die bonding. As shown in FIG. 4, a Sn foil 16 as a bonding material is first arranged on a predetermined position of the Cu wiring line 12 where die bonding is performed. The Sn foil 16 is processed into a size corresponding to the size of the semiconductor device 13 that is subjected to die bonding. Then, while the semiconductor device 13 is placed on the Sn foil 16, fusion bonding is performed in a H₂ reduction furnace.

The thickness of the Sn foil 16 is 14 to 72 μm, which is the same as the Sn thickness before bonding in the first embodiment. In this embodiment, the Sn foil 16, which is easy to process, is used, and therefore the cost is low in the same manner as in the case of using a conventional Pb-5Sn plate solder. Further, positioning can be easily performed using a jig in the same manner as in conventional plate soldering. Since the Sn foil 16 that has been processed into a predetermined thickness in advance is used, the thickness of the bonding part can be easily controlled.

In the case of this embodiment, the Sn plating 15 is not formed on the Cu wiring line 12, and therefore the surface of the Cu wiring line 12 is oxidized. However, the surface oxide layer can be easily reduced in a H₂ atmosphere, and therefore the joint state is not impaired when the operation is performed in the H₂ reduction furnace. Therefore, good bonding is achieved in the same manner as in the first embodiment in which the Sn plating 15 is performed on the entire surface of the Cu wiring line 12. Further, a Ni metal plating 17 may be performed on the surface of the Cu wiring line 12 for preventing the oxidation, as needed. When the Ni metal plating 17 is performed on the surface of the Cu wiring line 12, the following two additional advantages are obtained, in addition to oxidation prevention.

One of the advantages is as follows.

The IMC is formed on the interface of Cu almost simultaneously with the melting of Sn. Further, while Sn has good wettability, the IMC has poor wettability. Therefore, spreading of wetting by Sn is inhibited by the IMC formed on the interface before wetting by Sn having good wettability sufficiently spreads, which may result in easy formation of voids. Therefore, the wettability inhibition by the IMC can be suppressed by forming a Ni film having a suitable thickness on the surface of the Cu wiring line 12.

In this structure, the Ni film functions as an excellent barrier layer. Therefore, while Sn melts and the wetting spreads, the contact with Cu is avoided. Accordingly, the IMC is hardly formed, and therefore wetting by Sn having good wettability easily spreads on the surface of the Ni metal plating 17. Since the IMC is not formed in this state, the function as a high temperature bonding material is not obtained. However, the Ni film is deleted by controlling the thickness of the Ni film to an appropriate value so that Ni is diffused and dissolved in Sn after wetting by Sn spreads. Then, when the Ni film has been deleted, Cu and Sn contact each other to form the IMC.

That is, the Ni film delays the contact with Cu until Sn having good wettability melts and the wetting sufficiently spreads. This ensures the time for spreading of the wetting by Sn, by preventing the wetting inhibition due to the IMC formation immediately after the melting of Sn. Then, the IMC that functions as a high temperature bonding material is subsequently formed, and thus both good wetting by Sn and high temperature bonding by the IMC are achieved.

When the thickness of the Ni film is excessively large in order to obtain this action, the Ni layer that is a barrier layer is not torn after the wetting by Sn has spread, and therefore the IMC is not sufficiently formed. On the other hand, when the thickness of the Ni film is excessively small, the barrier layer is torn before the wetting by Sn sufficiently spreads, thereby forming the IMC. Therefore, the wetting by Sn may fail to sufficiently spread. Accordingly, it is important to control the thickness of the Ni film, and the thickness of the Ni film is about 1 to 15 μm, preferably about 1 to 5 μm.

The other advantage is as follows.

It is known that the crystal structure of Cu₆Sn₅ of the IMC transforms between hexagonal and monoclinic crystal forms depending on the temperature. The crystal structure with stable hexagonal crystal is taken at high temperatures, and the crystal structure with stable monoclinic crystal is taken at low temperatures. Further, with the change between the two crystal structures, the volume also changes. Specifically, with a change from the hexagonal crystal to the monoclinic crystal, the volume increases by about 2.15%. Therefore, this increase in volume may possibly cause cracks because it causes internal stress at the bonding part.

In contrast, when the Ni metal plating 17 is performed on the surface of the Cu wiring line 12, the IMC at the bonding interface forms (Cu,Ni)₆Sn₅. Even if the temperature changes, this IMC maintains the hexagonal crystal structure and does not undergo phase transformation. Therefore, the volume does not change, and the occurrence of internal stress at the bonding part is suppressed. Accordingly, the reliability of the bonding part is maintained high. In order to obtain the second advantage, Ni may be incorporated, for example, into the material of the Sn foil, other than forming a Ni film on the surface of the first member.

### Third Embodiment

Next, a third embodiment will be described. The third embodiment is the same as the second embodiment in that Sn that is necessary for constituting the bonding structure 20 is bonded by using a bonding material, instead of supplying it as the Sn plating 15 formed on the entire surface of the Cu wiring line 12. However, the third embodiment is significantly different from the second embodiment in that a bonding material composed of a plurality of layers is used instead of the Sn foil 16 composed of a single layer.

In the case of using the Sn foil 16, the appropriate thickness of the Sn foil 16 is about 14 to 72 μm as described above. This thickness is very small as compared with that in the conventional alloy solder material. For example, in the case of the Pb-5Sn plate solder that is often used for die bonding, a solder with a thickness of about 100 to 300 μm is generally used.

In the case of forming the IMC using the Sn foil 16 with a thickness of about 14 to 72 μm, the bonding thickness is small, which is therefore disadvantageous in view of the thermal shock resistance. That is, the bonding material with a small thickness cannot absorb the thermal stress sufficiently, and cracks tend to form.

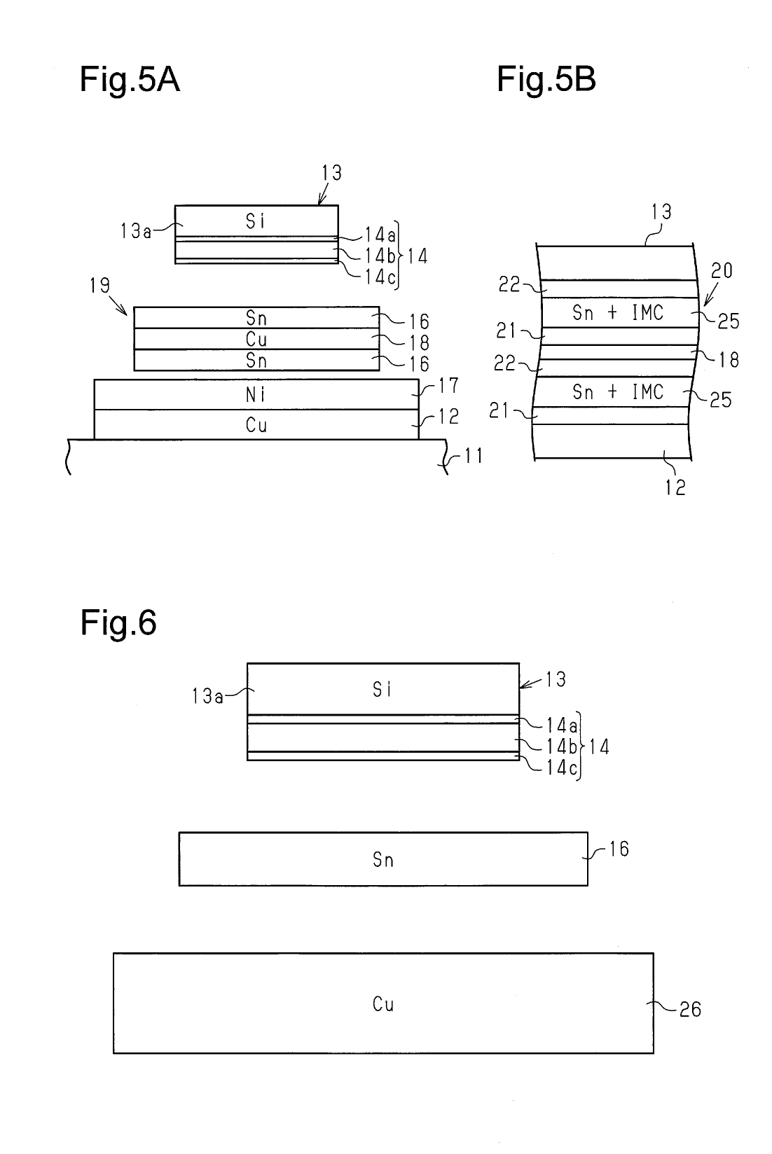

However, as described above, the IMC network needs to be formed in the Sn rich layer for the function as a high temperature bonding material while preventing remelting, and therefore increasing the thickness of the single layer Sn foil 16 to a value higher than about 14 μm to 72 μm is not preferable. Then, in order to solve this problem, multilayer Sn foils 16 are used, instead of the bonding material composed of the single layer Sn foil 16 arranged between the members. Specifically, as shown in FIG. 5A, a bonding material 19 having a three-layer structure of Sn foil/Cu foil/Sn foil obtained by disposing the Sn foils 16 on both surfaces of a Cu foil 18 is used.

First, the bonding material 19 having the three-layer structure is disposed on a predetermined position of the Cu wiring line 12 where die bonding is performed. The bonding material 19 is processed into a size corresponding to the size of the semiconductor device 13 that is subjected to die bonding. Then, while the semiconductor device 13 is placed on the bonding material 19, fusion bonding is performed in a H₂ reduction furnace. As a result, the bonding structure 20 is formed, as shown in FIG. 5B, so that a layer structure composed of the first IMC layer 21, the interlayer 25, and the second IMC layer 22 is present on each of both surfaces of the Cu foil (Cu layer) 18 between the Cu wiring line 12 and the semiconductor device 13.

The thickness of each Sn layer is about 14 to 72 μm, in the same manner as in the case where a single layer is used instead of the two Sn foils 16. The thickness of the Cu foil 18 is about 30 to 300 μm, preferably about 50 to 100 μm, in consideration of the handleability, the workability, the cost, and the like. This structure is a three-layer structure in which the Sn foils 16 are respectively disposed on the upper and lower sides of the Cu foil 18, and therefore the total thickness as a bonding material can be about 100 to 300 μm, which is at a level equivalent to that in conventional lead soldering.

Further, not only the stress relaxation effect by simply increasing the thickness but also a special stress relaxation effect is expected by disposing the Cu layer between the pair of Sn layers on the upper and lower sides. That is, as compared with Al, which is generally used for high heat dissipation metal circuit boards, the difference in linear expansion coefficient between the Cu foil 18 and the mounting part is small, and the thermal stress that occurs in the Cu foil 18 is also low. Therefore, the degree of change in linear expansion coefficient between the mounting board and the device is reduced by interposing a Cu material layer between Al of the mounting board and the device of the mounting part. Thus, the thermal stress is further relaxed.

Further, a Ni film may be formed on the surface of the Cu foil 18 in the three-layer structure. Further, the bonding material 19 may have a five-layer structure including two Cu layers, or a multilayer structure including five or more layers, other than the three-layer structure.

### Fourth Embodiment

Next, a fourth embodiment will be described. The fourth embodiment is different from the aforementioned embodiments in that the device electrode 14 of the semiconductor device 13 as the second member is bonded to the Cu plate as the first member via the bonding structure 20, instead of bonding the device electrode 14 of the semiconductor device 13 as the second member onto the Cu wiring line 12 as the first member formed on the wiring board 11.

As shown in FIG. 6, die bonding of the semiconductor device 13 onto a Cu plate 26 as the first member via the Sn foil 16 was performed. The device electrode 14 of the semiconductor device 13 was formed by layering the Ti layer 14a, the Ni layer 14b, and the Au layer 14c, sequentially from the device body 13a side. In this case, die bonding was performed using the Sn foil 16 having a thickness of 30 μm and 50 μm. The bonding was performed at about 440° C. in a H₂ reduction reflow furnace. As a result, reliable mounting was achieved.

For the wettability by the Sn foil 16 in bonding of the IMC of Sn and Cu, the void fraction was calculated from an X-ray image of the bonding part. As a result, the maximum void fraction was 3% or less with 30 μm thickness, and 2% or less with 50 μm thickness. Further, there were cases where the void fraction was about 1% in the two thicknesses, both of which showed good results.

In a relative comparison, the void fraction with 50 μm thickness was slightly better. The difference in the aforementioned void fraction due to the thickness of the Sn foil is considered to be caused by the wettability depending on the difference in the Sn amount. That is, the 50 μm thickness having a larger Sn amount is entirely spread more easily in the melting and is easily filled therein. Also on the appearance, fillets with a good shape are formed in the entire circumference of the semiconductor device 13, and no nest generation was observed.

Further, in order to check whether high temperature bonding was established, the Cu plate 26 after die bonding was vertically arranged and was reintroduced into a reflow furnace having a peak at 320° C. Then, the dropping and transition of the device and the formation of voids at the bonding part due to remelting were checked. As a result, the dropping and transition of the device did not occur. Further, also in the X-ray observation, no change was found inside the bonding part. From these results, it was confirmed that high temperature bonding up to at least 320° C. was formed.

That is, it was confirmed also in the fourth embodiment that IMC high temperature bonding of Sn and Cu was obtained using the Sn foil 16. Further, it was also confirmed that use of the Sn foil 16 allowed good IMC high temperature bonding of Sn and Cu to be obtained by handling in the same manner as in conventional Pb soldering.

The above described embodiments may be modified as follows.

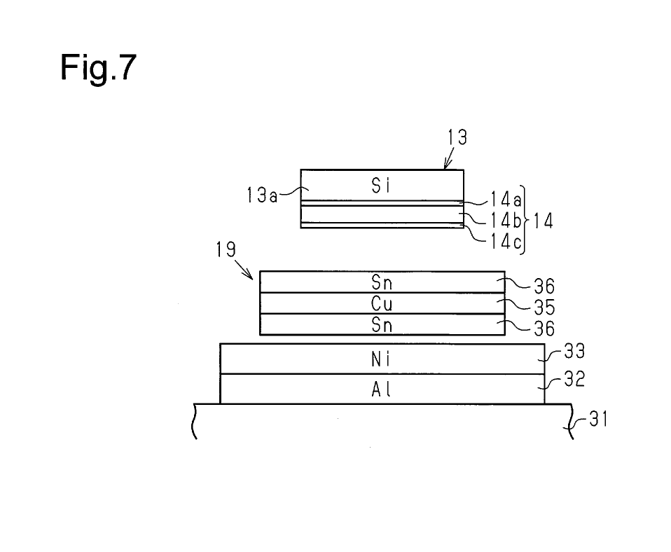

Instead of the substrate in which the Cu wiring line 12 is formed on the wiring board 11, a substrate in which an aluminum plate (metal plate) 32 is brazed onto a ceramic substrate (insulation plate) 31, which is called direct brazed aluminum (DBA) substrate, for example, may be used, as shown in FIG. 7. In this case, the bonding material 19 having two layers of a Cu layer 35 and a Sn layer 36 needs to be used. Further, a Ni layer 33 may be formed on the surface of the aluminum plate 32.

When providing a plurality of Sn layers, both surfaces of the Cu foil 18 may be subjected to Sn plating, instead of disposing the Sn foils 16 on both surfaces of the Cu foil 18. In this case, the Cu foil 18 is formed into a size corresponding to the shape of the mounting part. Therefore, metal plating may be performed on the entire surface of the Cu foil 18, and the masking process required in the case where Sn plating is performed only on the surface of the Cu wiring line 12 on the substrate is eliminated.

When providing a plurality of Sn layers and Cu layers, a clad material with the Sn layers and the Cu layers may be used as a bonding material, instead of disposing the Sn foils 16 and the Cu foils 18 by layering them between the members. In this case, there is no possibility of the formation of voids between the layers in bonding unlike the case where the bonding is performed by layering the Sn foils 16 and the Cu foils 18. Further, the workability is improved by disposing the cladded single material, as compared with the case of disposing many foil materials. Further, the total thickness of the bonding material can be accurately controlled by disposing the cladded single material.

Further, by disposing the cladded single material, the Sn material can be supplied by covering both surfaces of the Cu material to protect the surface of the core of the Cu material that is susceptible to oxidation, so that oxidation of Cu is suppressed. Further, by disposing the cladded single material, the supply is achieved while the layers are rolled in a close contact state, and therefore the strength in the bonding is improved. Further, the production cost is reduced by cladding as compared with the cases of using metal plating and foils for the layers.

The bonding material needs only to have a Cu layer and a Sn layer at least on the entire one surface of the Cu layer.

In the aforementioned bonding structure, Cu may be disposed between the first member and the second member before bonding the first member and the second member, using at least any one of the first member, the second member, or a layer of another member.

The bonding operation may be performed in a reduction furnace of a type other than the H₂ reduction furnace. For example, the bonding operation may be performed in a reduction furnace using formic acid.

Further, the bonding operation may be performed in a N₂ furnace instead of the reduction furnace. In this case, bonding at a practical level is sufficiently possible, although the wettability slightly decreases as compared to the case of performing the operation in a reduction furnace.

Further, when the board wiring as a bonding material is subjected to Sn plating or Ni plating in order to suppress the surface oxidation, the bonding operation may be performed in a normal air atmosphere furnace. In this case, bonding at a practical level is sufficiently possible, although the wettability slightly decreases as compared to the case of performing the operation in a reduction furnace.

### DESCRIPTION OF THE REFERENCE NUMERALS

12: Cu wiring as first member
13: Semiconductor device as second member
16: Sn foil
18: Cu foil
19: Bonding material
20: Bonding structure
21a: Cu₃Sn layer
21b: Cu₆Sn₅ layer
23: Sn
24: Network-like IMC
25: Interlayer
35: Cu layer
36: Sn layer

1. A bonding structure configured to bond a first member and a second member together, wherein
Sn layered on Cu is disposed between the first member and the second member before bonding,
Cu and Sn form an intermetallic compound to bond the first member and the second member together, and wherein
the intermetallic compound is
disposed as a layer on the entire surface of each of the interface of the first member and the interface of the second member at the bonding part, and
dispersed in the form of a network within a Sn rich layer present between the interface of the first member and the interface of the second member so as to connect the two interfaces.

2. (canceled)

3. The bonding structure according to claim 1, wherein the Cu is disposed, before the bonding, by at least any one of the first member, the second member, and a layer of another member.

4. The bonding structure according to claim 1, wherein the Sn and the Cu are layered in direct contact with each other.

5. The bonding structure according to claim 1, wherein the Sn and the Cu are layered with a Ni layer disposed between the Sn and the Cu.

6. The bonding structure according to claim 1, comprising, between the first member and the second member:
an intermetallic compound layer of Cu and Sn formed on the interface of the first member;
an intermetallic compound layer of Cu and Sn formed on the interface of the second member; and
an interlayer that is present between the two intermetallic compound layers and in which a network-like intermetallic compound of Cu and Sn is present in Sn.

7. The bonding structure according to claim 6, wherein the interface of one of the two intermetallic compound layers has larger asperities than the interface of the other intermetallic compound layer.

8. The bonding structure according to claim 6, wherein
the first member comprises Cu, and
the intermetallic compound layer of Cu and Sn formed on the interface of the first member comprises a Cu₃Sn layer and a Cu₆Sn₅ layer.

9. A bonding material comprising:
a Cu layer; and
a Sn layer present at least on the entire one surface of the Cu layer.

10. The bonding material according to claim 9, wherein the Cu layer and the Sn layer constitute a clad material.

11. The bonding material according to claim 9, wherein the Sn layer comprises a plating layer formed on the Cu layer.

12. The bonding material according to claim 9, wherein the Cu layer and the Sn layer comprise foils.

13. The bonding material according to claim 9, wherein
the Cu layer comprises a Cu plate, and
the Sn layer comprises of a foil.

14. A method for bonding a first member and a second member together, comprising:
heating Sn layered on Cu between the first member and the second member; thereby
forming a first intermetallic compound layer on the interface of the first member;
forming a second intermetallic compound layer on the interface of the second member; and
forming a network-like intermetallic compound between the first and second intermetallic compound layers.
